(19) United States
(12) Patent Application Publication
(10) Pub. No.: US 2010/0314701 A1
(43) Pub. Date: Dec. 16, 2010

(54) PRESSURE SENSOR AND MANUFACTURING METHOD THEREOF

(75) Inventors: Tomohisa Tokuda, Tokyo (JP); Hirofumi Tojo, Tokyo (JP)

Correspondence Address: MCDERMOTT WILL & EMERY LLP, 600 13TH STREET, N.W., WASHINGTON, DC, 20005-3096, US

(73) Assignee: YAMATAKE CORPORATION, Tokyo (JP)

(21) Appl. No.: 12/740,467

(22) PCT Filed: Oct. 29, 2008
(86) PCT No.: PCT/JP2008/069612

§ 371 Date: Apr. 29, 2010

(30) Foreign Application Priority Data
Oct. 30, 2007 (JP) 2007-281988
Oct. 30, 2007 (JP) 2007-281989

(51) Int. Cl. H01L 29/84; H01L 21/302; H01L 21/50

(52) U.S. Cl. 257/419; 438/53; 438/51; 257/E29.324; 257/E21.214; 257/E21.499

(57) ABSTRACT

A pressure sensor is provided with a sensor chip having a first semiconductor layer and a second semiconductor layer wherein a pressure-sensitive region is a diaphragm. In the pressure-sensitive region, an open section is formed on the first semiconductor layer, and a recessed section is formed on the second semiconductor layer in the pressure-sensitive region. The recessed section on the second semiconductor layer is larger than the opening section on the first semiconductor layer. An insulating layer may be arranged between the first semiconductor layer and the second semiconductor layer.

### CROSS REFERENCE TO PRIOR APPLICATIONS

This application is a U.S. National Phase application under 35 U.S.C. §371 of International Application No. PCT/JP2008/069612, filed on Oct. 29, 2008 and claims benefit to Japanese Patent Application Nos. JP 2007-281988 and JP 2007-281989, filed on Oct. 30, 2007. The International Application was published in Japanese on May 7, 2009 as WO 2009/057620 under PCT Article 21(2). All these applications are herein incorporated by reference.

### FIELD OF THE INVENTION

The present invention relates to a pressure sensor and to the method of manufacturing thereof, and, in particular, relates to a pressure sensor having a diaphragm, and to the method of manufacturing thereof.

### BACKGROUND OF THE INVENTION

Pressure sensors that use the semiconductor piezoresistance effect are small, lightweight, and highly sensitive, and thus are used broadly in fields such as industrial instrumentation, medical care, and the like. In such pressure sensors, strain gauges are formed on semiconductor diaphragms. The strain gauge deforms in accordance with the pressure applied to the diaphragm. A change in resistance of the strain gauge, due to the piezoresistance effect, is detected to measure the pressure. In order to mitigate the stresses from the packages, sensor chips wherein diaphragms are formed are bonded to platforms made out of glass, or the like. An example of this is disclosed in Japanese Unexamined Patent Application Publication 2002-277337, which is hereby incorporated by reference in its entirety.

The diaphragm is formed through hollowing out of a semiconductor wafer through etching. The thickness of the diaphragm has an extremely large influence on the characteristics of the pressure sensor. Consequently, the thickness of the diaphragm, that is, the amount of etching, must be controlled precisely. Given this, a technology has been disclosed wherein an etching stopper layer is formed from an insulating layer on the semiconductor wafer. An example of this is disclosed in Japanese Unexamined Patent Application Publication 2000-171318, which is hereby incorporated by reference in its entirety.

### SUMMARY OF THE INVENTION

FIG. 7 looked will be used to explain a structure for a pressure sensor. FIG. 7 is a side view cross-sectional diagram illustrating a structure of a conventional pressure sensor. A sensor chip 10 is formed from, for example, a single crystal silicon substrate. Strain gauges 5 and 15, having piezoresistance effects, are formed in the sensor chip 10. The center portion of the sensor chip 10 is etched to form a diaphragm 4. Here the center portion of the sensor chip 10 is etched into a tapered shape. As a result, the dimension of the opening of the diaphragm sensor on the back surface of the sensor chip will be larger than the dimension of the diaphragm. A base 11 is bonded to the chip 10. The base 11 is bonded to the sensor chip 10 at the peripheral portion of the diaphragm 4.

Additionally, an example of a structure of a pressure sensor having a semiconductor substrate that has an etching stop layer will be explained using FIG. 8. FIG. 8 is a side view cross-sectional diagram of the structure of the pressure sensor. As illustrated in FIG. 8, in the pressure sensor, and SiO₂ layer 42 is provided between an N-type single crystal silicon layer 41 and an N-type single crystal silicon layer 43. The N-type single crystal silicon layer 41 in the pressure sensitive region is etched using the SiO₂ layer 42 as an etching stopper layer (first etching). Furthermore, the SiO₂ layer 42 in the pressure sensitive region is also etched. The N-type single crystal silicon layer 43 is then etched (second etching) to form a diaphragm 44. The strain gauge 45 is formed in the N-type single crystal silicon layer 43.

This pressure sensor enables the N-type single crystal silicon layer 43 of the diaphragm 44 to have a uniform thickness because a specific amount of the N-type single crystal silicon layer 43 is etched. The SiO₂ layer 42 of the diaphragm 44 and of the diaphragm edge portion 46 can also be removed. This makes it possible to increase the strength of the diaphragm edge portion 46.

However, it has been discovered by the inventors in the present application that, in the manufacturing method set forth above, locations known as notches wherein stresses are concentrated are formed in the diaphragm edge portion 46. That is, with high pressures (for example, 3 MPa or more), stresses are concentrated in the notches, reducing the withstand pressure, leading to chip breakage. The reason for this is as explained below.

When etching the N-type single crystal silicon layer 43, side etching occurs in the side walls of the N-type single crystal silicon layer 41 and the SiO₂ layer 42. Consequently, the SiO₂ layer 42 is exposed due to the etching rate differential in the diaphragm edge portion 46, and notches are formed in the N-type single crystal silicon layer 41 through the accumulation of charge in the SiO₂ layer 42, a typical mechanism by which notches are formed. In the notches, the N-type single crystal silicon layer 41 is etched more than the side wall surface of the SiO₂. In particular, isotropic etching is used in the second etching in order to form an R-shaped N-type single crystal silicon layer 43 in order to distribute the stress. That is, using isotropic etching to form an R-shape in the end portion of the N-type single crystal silicon layer 43 can distribute the stress. When the N-type single crystal silicon layer 43 is processed using isotropic etching, the side etching rate of the N-type single crystal silicon layer 41 is increased. It is because of this that the aforementioned notches are formed, and the stresses concentrate therein, reducing the withstand pressure, leading to chip breakage. The withstand pressure performance is adversely affected in this way.

In order to increase the pressure sensitivity of the pressure sensor, it is necessary to increase the size of the diaphragm 4. Maintaining the strength of the bond to the base 11 requires the area of the bonding region to be increased. However, if the size of the sensor chip 10 is held constant, then the area of the bonding with the base is reduced by increasing the size of the diaphragm 4 in order to increase the sensitivity, where increasing the area of bonding in order to increase the reliability of bonding causes the size of the diaphragm 4 to be smaller. Consequently, there is a problem in that the sensor chip 10 must be made larger in order to ensure the bonding strength while increasing the pressure sensitivity. Consequently, with the structure in FIG. 7, it is difficult to achieve miniaturization of the pressure sensor while improving performance.

The present invention is to resolve this type of problem area, and the object thereof is to provide a high-performance pressure sensor and a manufacturing method thereof.

A pressure sensor as set forth in one aspect of the present invention is a pressure sensor having a sensor chip provided with a first semiconductor layer and a second semiconductor layer wherein a pressure sensitive region is a diaphragm, wherein: in the pressure sensitive region, an opening portion is formed in the first semiconductor layer; and a recessed portion is formed in the second semiconductor layer in the pressure sensitive region; wherein the recessed portion of the second semiconductor layer is larger than the opening portion of the first semiconductor layer. This enables the pressure sensitive region to be made larger, enabling an increase in the measurement sensitivity. This enables a high-performance pressure sensor.

A pressure sensor according to another aspect of the present invention is a pressure sensor having a first semiconductor layer, an insulating layer formed on the first semiconductor layer, and a second semiconductor layer wherein a pressure sensitive region is a diaphragm, wherein: in the pressure sensitive region, an opening portion is formed in the first semiconductor layer and the insulating layer, and a recessed portion is formed in the second semiconductor layer in the pressure sensitive region, wherein: in the interface between the insulating region and the first semiconductor layer, the positions of the side edges of the first semiconductor layer and of the insulating layer are coincident on the pressure sensitive region side. This makes it possible to mitigate the concentration of stresses in the notched portions, enabling an improvement in the withstand pressure characteristics. This enables a high-performance pressure sensor.

In the aforementioned pressure sensor, there may be the distinctive characteristic that the recessed portion formed in the second semiconductor layer is larger than the opening portion of the insulating layer. This enables the pressure sensitive region to be made larger, enabling an improvement in the measurement sensitivity. This enables a high-performance pressure sensor.

In the pressure sensor set forth above, the shape of the diaphragm may form a polygon shape. In the pressure sensor set forth above, the shape of the diaphragm may form a circular shape.

The aforementioned pressure sensor may be provided with a base that is bonded to a sensor chip, and there may be a non-bonded portion wherein a gap is provided between the base and the sensor chip at the periphery of the bonded portion between the base and the sensor chip.

A method for manufacturing a pressure sensor as set forth in one aspect of the present invention is a method for manufacturing a pressure sensor having a sensor chip provided with a first semiconductor layer and a second semiconductor layer wherein a pressure sensitive region forms a diaphragm, comprising: a step for etching the first semiconductor layer in an area that will form the pressure sensitive region; a step for forming a passivating layer on the side wall of the first semiconductor layer; and a step, after the formation of the passivating layer, for etching the second semiconductor layer in the portion that will form the pressure sensitive region, to form the diaphragm. Doing so enables the second semiconductor layer to be etched with the first semiconductor layer in a protected state. This enables an improvement in the control of the etching, enabling the manufacturing of a high-performance pressure sensor.

In the pressure sensor set forth above, in the step for forming the diaphragm, the second semiconductor layer may be etched to form, in the second semiconductor layer, a recessed portion that is larger than the first etched portion. Doing so enables a pressure sensor that is small with high bonding reliability.

A method for manufacturing a pressure sensor as set forth in another aspect according to the present invention is a method for manufacturing a pressure sensor wherein an insulating layer is provided between a first semiconductor layer and a second semiconductor layer that will structure a diaphragm, comprising: a step for etching the first semiconductor layer in a portion that will form a pressure sensitive region; a step for etching the insulating layer in the portion for forming the pressure sensitive region; a step for forming a passivating layer on the side wall of the first semiconductor layer; and a step, after the passivating layer is formed, for etching the second semiconductor layer in the portion for forming the pressure sensitive region, to form the diaphragm. Doing so enables the second semiconductor layer to be etched with the first semiconductor layer in a protected state. This enables an increase in the control of the etching, enabling the manufacturing of a high-performance pressure sensor.

In the pressure sensor set forth above, the second semiconductor layer may be etched in the step for forming the diaphragm, to form a recessed portion in the second semiconductor layer that is larger than the etched portion in the insulating layer.

In the pressure sensor set forth above, the process for etching the first semiconductor layer may have the distinctive feature of using the insulating layer as an etching stopper. Doing so enables an increase in the control of the etching, enabling the manufacturing of a high-performance pressure sensor.

In the pressure sensor set forth above, the passivating layer may be formed from a fluorocarbon layer. Doing so enables the passivating layer to be formed easily, enabling an improvement in the manufacturability.

In the pressure sensor set forth above, the diaphragm may be shaped in a polygon shape. Additionally, in the pressure sensor set forth above, the diaphragm may be shaped in a circular shape.

The pressure sensor set forth above may further be provided with a step for bonding a base to the sensor chip, and a non-bonded portion wherein a gap is provided between the base and the sensor chip may be formed are the periphery of a bonded portion between the base and the sensor chip.

The present invention enables, through the above, the pressure sensitive region to be made larger, enabling an improvement in the measurement sensitivity, thus enabling the provision of a high-performance pressure sensor and the manufacturing method thereof.

### BRIEF DESCRIPTION OF THE DRAWINGS

The forgoing and other features of the present invention will be more readily apparent from the following detailed description and drawings of illustrative ennoblements of the invention in which;

FIG. 1 is a side view cross-sectional diagram illustrating a structure for a pressure sensor as set forth in a first form of embodiment according to the present invention.

FIG. 2A is a plan view illustrating the structure of the pressure sensor as set forth in the first form of embodiment according to the present invention.

FIG. 2B is a plan view illustrating the structure of the pressure sensor as set forth in the first form of embodiment according to the present invention.

FIG. 2C is a plan view illustrating the structure of the pressure sensor as set forth in the first form of embodiment according to the present invention.

FIG. 3A is a process cross-sectional diagram illustrating a manufacturing process for the pressure sensor as set forth in the first form of embodiment according to the present invention.

FIG. 3B is a process cross-sectional diagram illustrating a manufacturing process for the pressure sensor as set forth in the first form of embodiment according to the present invention.

FIG. 3C is a process cross-sectional diagram illustrating a manufacturing process for the pressure sensor as set forth in the first form of embodiment according to the present invention.

FIG. 3D is a process cross-sectional diagram illustrating a manufacturing process for the pressure sensor as set forth in the first form of embodiment according to the present invention.

FIG. 3E is a process cross-sectional diagram illustrating a manufacturing process for the pressure sensor as set forth in the first form of embodiment according to the present invention.

FIG. 3F is a process cross-sectional diagram illustrating a manufacturing process for the pressure sensor as set forth in the first form of embodiment according to the present invention.

FIG. 4 is a side view cross-sectional diagram illustrating a structure for a pressure sensor as set forth in a second form of embodiment according to the present invention.

FIG. 5 is a plan view illustrating the structure of the pressure sensor as set forth in the second form of embodiment according to the present invention.

FIG. 6A is a process cross-sectional diagram illustrating a manufacturing process for the pressure sensor as set forth in the second form of embodiment according to the present invention.

FIG. 6B is a process cross-sectional diagram illustrating a manufacturing process for the pressure sensor as set forth in the second form of embodiment according to the present invention.

FIG. 6C is a process cross-sectional diagram illustrating a manufacturing process for the pressure sensor as set forth in the second form of embodiment according to the present invention.

FIG. 6D is a process cross-sectional diagram illustrating a manufacturing process for the pressure sensor as set forth in the second form of embodiment according to the present invention.

FIG. 6E is a process cross-sectional diagram illustrating a manufacturing process for the pressure sensor as set forth in the second form of embodiment according to the present invention.

FIG. 6F is a process cross-sectional diagram illustrating a manufacturing process for the pressure sensor as set forth in the second form of embodiment according to the present invention.

FIG. 6G is a process cross-sectional diagram illustrating a manufacturing process for the pressure sensor as set forth in the second form of embodiment according to the present invention.

FIG. 7 is a side view cross-sectional diagram of a structure of a conventional pressure sensor.

FIG. 8 is a side view cross-sectional diagram of a structure of a conventional pressure sensor.

### DETAILED DESCRIPTION OF THE INVENTION

### Example of Embodiment 1

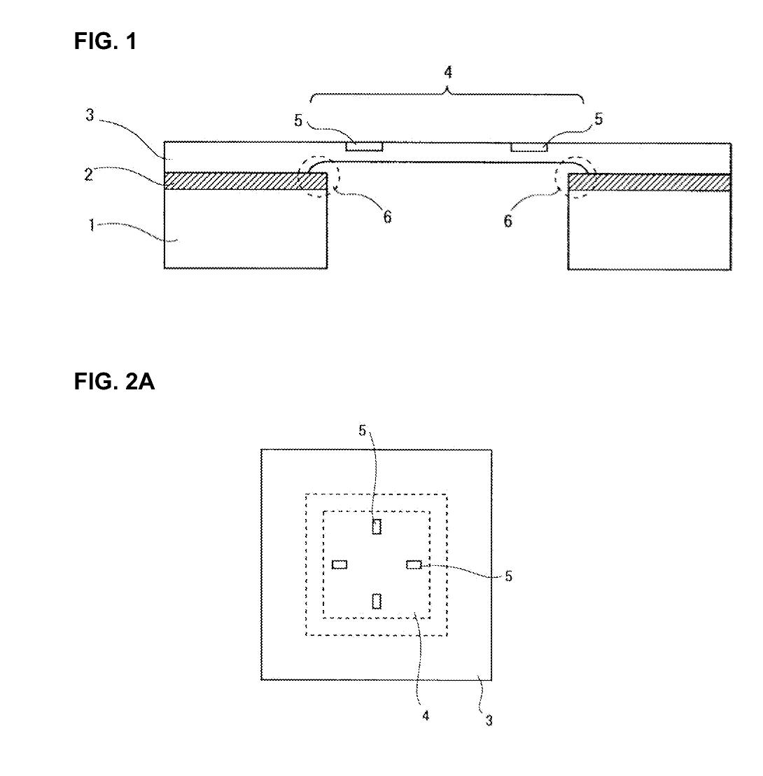

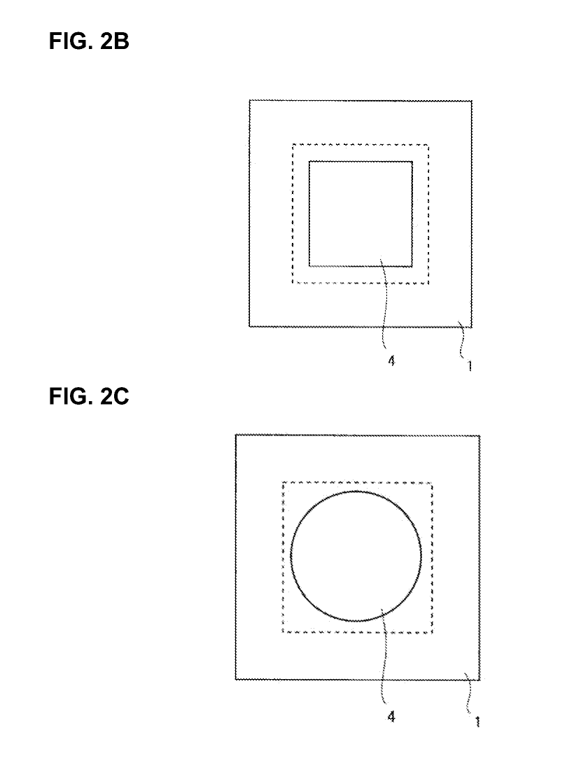

A specific form of embodiment to which the present invention is applied will be explained in detail below in reference to the drawings. FIG. 1 is a side view cross-sectional diagram illustrating a structure for a pressure sensor as set forth in the present form of embodiment. FIG. 2A is a top view illustrating the structure of the pressure sensor, and FIG. 2B is a bottom view illustrating the structure of the pressure sensor. The pressure sensor as set forth in the present form of embodiment is a semiconductor sensor that uses the semiconductor piezoresistance effect.

The pressure sensor is provided with a first semiconductor layer 1, that serves as a substrate, an insulating layer 2, and a second semiconductor layer 3. The first semiconductor layer 1 and the second semiconductor layer 3 are structured from, for example, N-type single crystal silicon layers. The insulating layer 2 is structured from, for example, an SiO₂ layer. The insulating layer 2 is formed on top of the first semiconductor layer 1. Additionally, the second semiconductor layer 3 is formed on top of the insulating layer 2. Consequently, the insulating layer 2 is disposed between the first semiconductor layer 1 and the second semiconductor layer 3. The insulating layer 2 has the function of an etching stopper when etching the first semiconductor layer 1. The second semiconductor layer 3 structures the diaphragm 4. As illustrated in FIG. 2A and FIG. 2B, the diaphragm 4 is provided in the center portion of the chip.

In the portion that will form the pressure sensitive region, an opening portion is formed in the first semiconductor layer 1 and the insulating layer 2, to expose the second semiconductor layer 3. That is, in the central portion of the pressure sensor, which will form the pressure sensitive region, both sides of the second semiconductor layer 3 are exposed. Then a recessed portion is formed in the second semiconductor layer 3 in the portion that will form the pressure sensitive region. That is, the thickness of the second semiconductor layer 3 is thinner relative to the other portions in the portion that is to form the pressure sensitive region. The portion wherein the second semiconductor layer 3 is thinned in this way forms the diaphragm 4 for measuring the pressure. Here, in the top view, the diaphragm 4 is formed into a square. The region corresponding to the square-shaped diaphragm 4 forms the pressure sensitive region of the pressure sensor. The diaphragm 4 may be circular or may be a polygon. When the diaphragm 4 is circular, then, as illustrated in FIG. 2C, the centers of the circular diaphragm 4 and of the square sensor chip 10 are arranged so as to be coincident. Note that FIG. 2C is a bottom view illustrating the structure of the pressure sensor when the diaphragm 4 is circular. As will be discussed below, strain gauges 5 are formed in the circular diaphragm 4.

The strain gauges 5 are formed on the top surface side of the second semiconductor layer 3. The strain gauges 5, which have a piezoresistance effect, are provided on the diaphragm 4. Here four strain gauges 5 are formed in the second semiconductor layer 3. Note that metal electrodes (not shown) for connecting the strain gauges 5 are formed on the top surface of the second semiconductor layer 3. Furthermore, the four strain gauges 5 are connected in a bridge circuit. The diaphragm 4 deforms due to the differential pressure of the spaces that are partitioned by the diaphragm 4. In the strain gauges 5, the resistances vary according to the amount of deformation of the diaphragm 4. The pressure can be measured by detecting these changes in resistance.

Here the vicinities of both ends of the diaphragm 4 are defined as the diaphragm edge portions 6. At the diaphragm edge portions 6, the positions of the side edge of the first semiconductor layer 1 and the side edge of the insulating layer are coincident at the interface between the first semiconductor layer 1 and the insulating layer 2. That is, on the pressure sensitive region side, the side edge of the first semiconductor layer 1 and the side edge of the insulating layer are at the same position. Consequently, this forms a notch free structure, enabling a reduction in the concentration of stresses, even at high pressures (for example, in excess of 3 MPa). This is able to suppress reductions in the withstand pressure of the pressure sensor, and suppress chip breakage. Additionally, in the diaphragm edge portion 6, the side edge of the second semiconductor layer 3 extends beyond the outside of the opening portion that is formed in the first semiconductor layer 1 and the insulating layer 2. The side edge of the second semiconductor layer 3 is processed into an R-shape. The concentration of stresses is mitigated thereby.

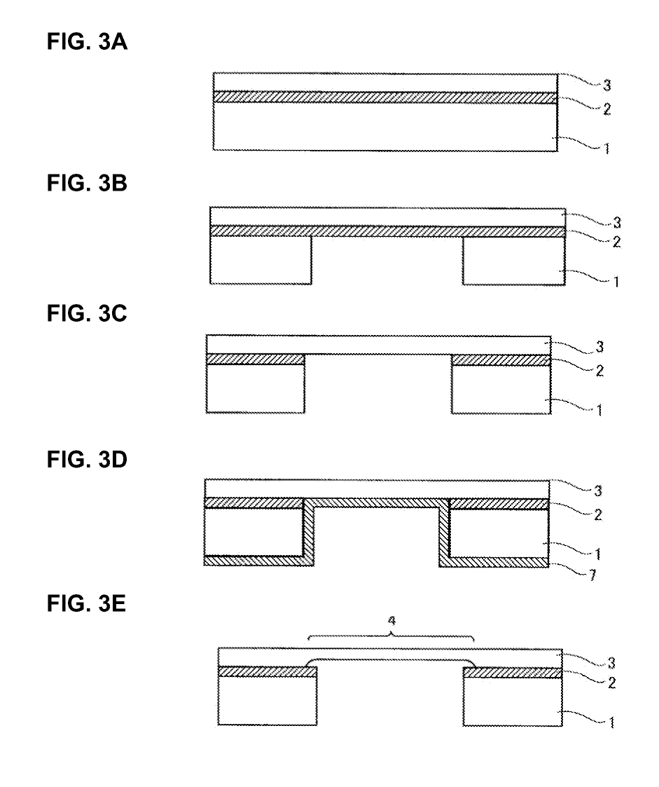

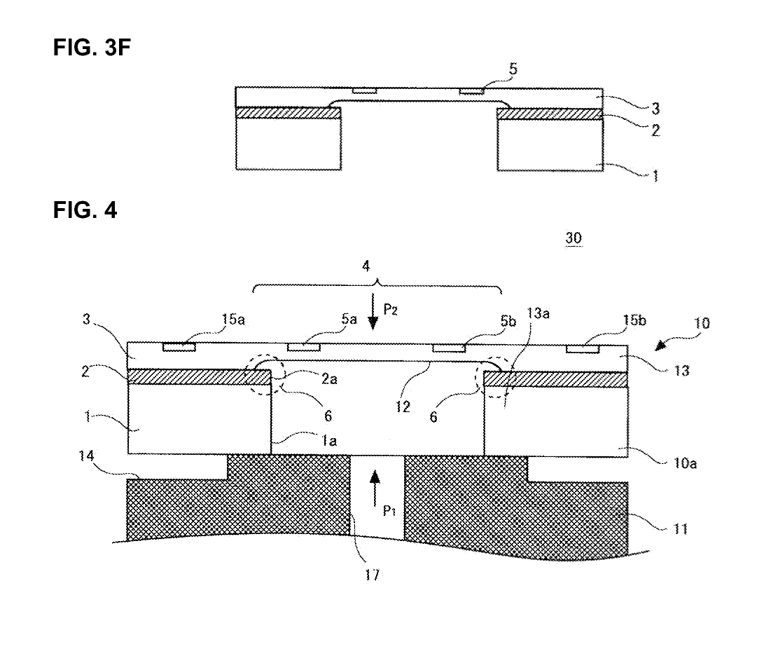

FIG. 3A through FIG. 3F will be used next to explain the method for manufacturing the pressure sensor. FIG. 3A through FIG. 3F are process cross-sectional diagrams illustrating the method for manufacturing the semiconductor sensor. First, as illustrated in FIG. 3A, a Silicon On Insulator (SOI) wafer is prepared, comprising the first semiconductor layer 1, an insulating layer 2 that is approximately 0.5 μm thick, and the second semiconductor layer 3. In fabricating this SOI wafer, the SIMOX (Separation by IMplanted OXygen) technology wherein an SiO₂ layer is produced through implanting oxygen into a silicon substrate may be used, the SDB (Silicon Direct Bonding) technology, wherein two silicon substrates are bonded together, may be used, or another method may be used.

The second semiconductor layer 3 is planarized and reduced in thickness. For example, the second semiconductor layer 3 is polished to a specific thickness (for example 80 μm) using, for example, the polishing method known as CCP (Computer-Controlled Polishing).

An SiO₂ layer or a resist (not shown) is formed on the bottom surface of the SOI wafer that is formed in this way. An opening portion is formed in the SiO₂ layer or the resist in a portion corresponding to the pressure sensitive region (the region wherein the diaphragm 4 will be formed). After this, the SiO₂ layer or resist patterned in this way is used as an etching mask for forming the diaphragm, and the first semiconductor layer 1 is etched (first etching). Here the first semiconductor layer 1 is processed through dry etching. More specifically, the first semiconductor layer 1 is etched through an ICP Bosch process. Anisotropic etching is performed through the Bosch process, and thus the side wall surfaces of the first semiconductor layer 1 are essentially vertical, as illustrated in FIG. 3B.

Note that in the Bosch process an etching step and a passivating step (deposition step) are performed alternatingly. The etching step and the passivating step are alternated every few seconds. In the etching step, isotropic etching is performed using, for example, SF₆ gas. In the passivating step, the side walls are protected using a fluorocarbon gas (such as C₄F₈). That is, a layer for protecting the side walls is deposited on the first semiconductor layer 1. Doing so suppresses the side etching in the etching step. This makes it possible to perform anisotropic etching on the first semiconductor layer 1. Using the Bosch process in this way makes it possible to etch the silicon deeply, to form a vertical trench structure.

Here the insulating layer 2 functions as an etching stopper. Because of this, the etching advances steadily in the aforementioned opening portion, but stops automatically when it arrives at the insulating layer 2. In this way, the first semiconductor layer 1 is removed until the insulating layer 2 is exposed. This forms an opening portion in the first semiconductor layer 1 to expose the insulating layer 2 in the center portion of the chip that will form the pressure sensor. Of course, the first semiconductor layer 1 may be etched using wet etching instead, using a solution such as KOH or TMAH. In this case, the first semiconductor layer 1 would be processed into a tapered shape.

Following this, the first semiconductor layer 1 is used as an etching mask when etching the insulating layer 2. The insulating layer 2 is processed through wet etching using, for example, a solution such as HF. Of course, the insulating layer 2 may be etched using a different etchant instead, or maybe etched using dry etching. The insulating layer 2 that was exposed through etching the first semiconductor layer 1 is removed, to form the structure illustrated in FIG. 3C. In this way, an opening portion is formed in the first semiconductor layer 1 and the insulating layer 2, to expose the second semiconductor layer 3 in the portion that will form the pressure sensitive region. Here the diameters of the opening portions in the first semiconductor layer 1 and the insulating layer 2 are essentially identical.

Additionally, when a passivating layer 7 is formed to a specific thickness on the surface of the wafer, the structure will be as illustrated in FIG. 3D. The passivating layer 7 is formed over the entirety of the wafer surface. Consequently, the passivating layer 7 is formed covering the first semiconductor layer 1. The passivating layer 7 is also formed on the side surfaces of the insulating layer 2 and on the exposed portion of the second semiconductor layer 3. That is, the passivating layer 7 is deposited on the surface of the second semiconductor layer 3 in the portion at which the opening portion is formed in the first semiconductor layer 1 and the insulating layer 2. The passivating layer 7 protects the first semiconductor layer 1 from side etching in the etching process for the second semiconductor layer 3, described below.

The passivating layer 7 is formed through performing, for example, the passivating step of the Bosch process. That is, the passivating layer 7 is deposited using a gas that includes carbon atoms and fluorine atoms, such as C₄F₈. Here the passivating layer is formed from a fluorocarbon layer, because of the use of the fluorocarbon gas. This deposits the passivating layer 7 over the entirety of the surface of the wafer. Note that the passivating layer may be formed through repeating a passivating step that is several seconds long, or the passivating layer 7 may be formed through performing a continuous passivating step over an extended period of time. Furthermore, the passivating layer may instead be formed through a process other than the Bosch process. For example, the passivating layer may be formed from photoresist, or the like. Conversely, the passivating layer 7 may be deposited using a chemical vapor deposition (CVD) process, or the like. Furthermore, the passivating layer 7 is formed to a thickness such that there will be no side etching of the first semiconductor layer 1 in the subsequent process for etching the second semiconductor layer 3. That is, the thickness to which the passivating layer 7 is formed is set in consideration of the amount of etching for the second semiconductor layer 3. Furthermore, the passivating layer 7 need not be formed on the other portions, insofar as it is formed on the side walls of the first semiconductor layer 1.

Thereafter, with the passivating layer 7 having been formed, the second semiconductor layer 3 is etched (second etching). Doing so forms a recessed portion in the second semiconductor layer 3 that will form the diaphragm 4. Here a Bosch process etching step may be used. That is, dry etching is performed using a gas (SF₆) that contains sulfur atoms and fluorine atoms. Side etching of the first semiconductor layer 1 is suppressed because of the formation of the passivating layer 7 on the side walls of the first semiconductor layer 1. Because of this, the first semiconductor layer 1 is not etched, and no notch is formed at the interface between the first semiconductor layer 1 and the insulating layer 2. That is, it is possible to position the side edge of the first semiconductor layer 1 in the same position as the side edge of the insulating layer 2 at the interface between the first semiconductor layer 1 and the insulating layer 2. On the pressure sensitive region side, the side edge of the first semiconductor layer 1 and the side edge of the insulating layer 2 can be positioned coincidentally. Note that the depth of etching of the second semiconductor layer 3 is controlled to a specific minute value (between about 5 and 50 μm) through time control.

Additionally, performing the dry etching in a state wherein a bias voltage is applied to the second semiconductor layer 3 accelerates the ions towards the second semiconductor layer 3. Because of this, the velocity of the ions in the vertical direction will be higher than the velocity in the horizontal direction. The majority of the ions within the plasma will be directed towards the second semiconductor layer 3 in the opening portion of the first semiconductor layer 1 and the insulating layer 2. Consequently, the frequency of ion impingement on the passivating layer 7 that is formed on the surface of the second semiconductor layer 3 will be high, causing the passivating layer 7 that is formed on the surface of the second semiconductor layer 3 to be etched with a somewhat elevated etching rate. Given this, the passivating layer 7 that is formed on the surface of the second semiconductor layer 3 will be removed quickly, exposing the second semiconductor layer 3.

On the other hand, the frequency of ion impingement on the passivating layer 7 that is provided on the side walls of the first semiconductor layer 1, for the same reasons set forth above, will be relatively low, so the etching rate of the passivating layer 7 that is formed on the side wall surfaces of the first semiconductor layer 1 will be reduced. Consequently, the etching rate in the vertical direction of the passivating layer 7 in the opening portion will be higher than the etching rate in the horizontal direction. As a result, the second semiconductor layer 3 will be etched in a state wherein the passivating layer 7 that is formed on the side wall surfaces of the first semiconductor layer 1 is still in place. The side walls of the first semiconductor layer 1 will not be etched, enabling a notch-free structure, wherein there are no locations wherein stresses are concentrated.

Furthermore, when the passivating layer 7 is removed from the surface of the second semiconductor layer 3 to expose the second semiconductor layer 3, the second semiconductor layer 3 is then etched isotropically. Consequently, there will be side etching of the second semiconductor layer 3. The portion of the second semiconductor layer 3 that is removed through side etching will extend beyond the outside of the opening portion formed in the first semiconductor layer 1 and the insulating layer 2. That is, the location of the side edge of the second semiconductor layer 3 will be offsetted from the location of the side edges of the first semiconductor layer 1 and the insulating layer 2. The recessed portion for forming the diaphragm 4 will be larger than the opening portion in the first semiconductor layer 1 and the insulating layer 2. Following this, when the wafer is cleaned in a chemical solution, or the like, and the passivating layer 7 that is formed on the wafer is removed, the structure will be as illustrated in FIG. 3E. In this way, side etching is performed on the second semiconductor layer 3 to form a recessed portion, in the second semiconductor layer 3, that is larger than the etched portion of the insulating layer 2. Doing so enables the pressure sensitive area to be made larger. The side edges of the second semiconductor layer 3 are processed into an R-shape through side etching. This enables the mitigation of the concentration of stresses.

Doing this forms a diaphragm 4 in the second semiconductor layer 3. The etching of the second semiconductor layer 3 is a minute amount, between about 5 and 50 μm, so there is no variability in the thickness of the etching, and thus the diaphragm 4 can be formed with a uniform thickness. This enables an improvement in the measurement accuracy. This also enables an increase in strength of the diaphragm edge portion 6.

Furthermore, the Bosch process passivating step is used in the process for forming the passivating layer 7, and the Bosch process etching step, and the like, is used in the process of etching the second semiconductor layer 3. Doing so enables continuous processing within the same equipment, enabling an increase in productivity. Furthermore, because the same equipment can be used through using the Bosch process in the first etching, this enables an even greater increase in productivity. Of course, the second semiconductor layer 3 may instead be etched through a different etching process.

Strain gauges (piezoresistance regions) 5 are formed from P-type silicon through diffusion of impurities or through ion implantation into the top surface of the second semiconductor layer 3. The strain gauges 5 are formed in the diaphragm 4 of the second semiconductor layer 3. This causes the structure to be as illustrated in FIG. 3F. Following this, an SiO₂ layer (not shown) is formed on the top surface of the second semiconductor layer 3, and after the formation of contact holes in the SiO₂ layer over the strain gauges 5, metal electrodes (not shown) are deposited through vapor deposition in order to make electrical contact with the strain gauges 5 at the contact hole portions. Note that the process for forming the metal electrodes may be performed anywhere between FIG. 3A and FIG. 3E. The fabrication of the pressure sensor is completed thereby. Of course, the chip described above may be attached to a base, or the like.

As described above, the second etching is performed in a state wherein the passivating layer 7 is formed on the side walls of the first semiconductor layer 1. This enables the prevention of the formation of notches at the side edges of the pressure sensitive region of the first semiconductor layer 1 at the interface between the first semiconductor layer 1 and the insulating layer 2. This enables the mitigation of the concentration of stresses. This enables a reduction in the deleterious effect on the withstand pressure, and enables the prevention of chip breakage. In simulations, the notch-free structure set forth above is able to reduce by approximately 34% the stresses that are concentrated in the diaphragm edge portion 6 when 3 MPa is applied. This enables a reduction in the deleterious effect on withstand pressure, enabling a diaphragm structure with high withstand pressure. Furthermore, performing the second etching using isotropic etching enables the recessed portion in the second semiconductor layer 3 to be made larger. Doing so enables the area of the pressure sensitive region to be made larger. Furthermore, processing the side edge of the second semiconductor layer 3 on the pressure sensitive region side into the R-shape enables the mitigation of the concentration of stresses. This enables an increase in the withstand pressure strength. Doing so enables a high-performance sensor.

### Example of Embodiment 2

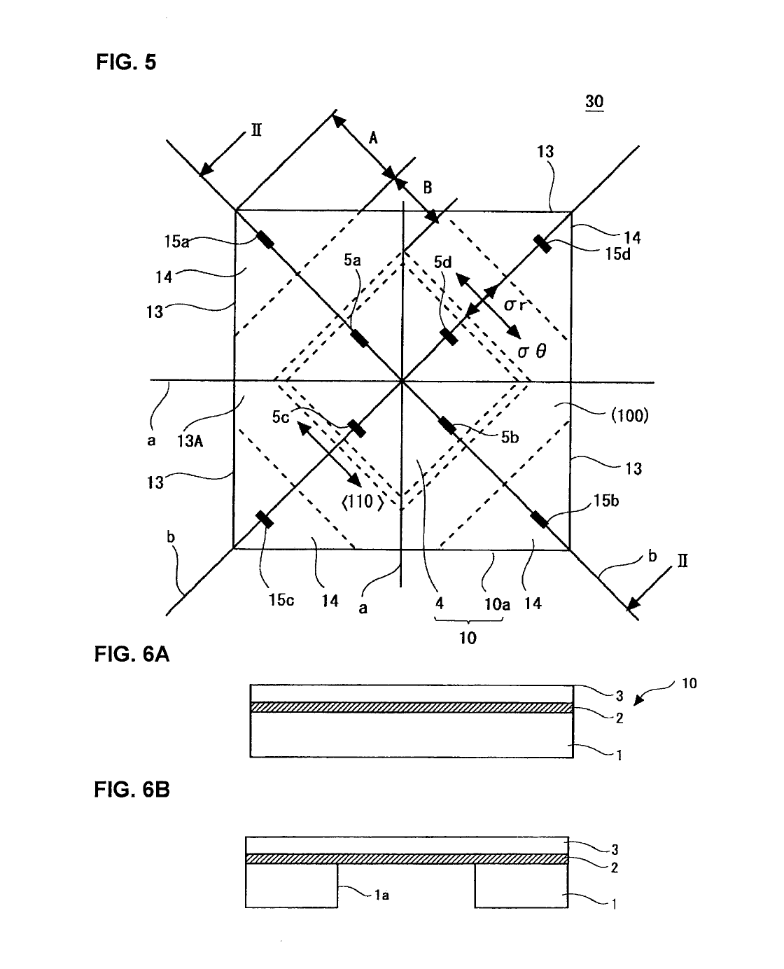

A specific form of embodiment to which the present invention is applied will be explained in detail, referencing the drawings. FIG. 4 is a side view cross-sectional diagram illustrating the structure of a pressure sensor as set forth in the present form of embodiment. FIG. 5 is a top view of the pressure sensor. FIG. 4 is a cross-sectional diagram along the section II-II in FIG. 5, where the pressure sensor as set forth in the present form of embodiment is a semiconductor pressure sensor that uses the semiconductor piezoresistance effect.

A pressure sensor 30 comprises a square sensor chip 10, made from an N-type single crystal silicon with the crystal plane orientation being the (100) plane, and a base 11 to which the sensor chip 10 is bonded. The sensor chip 10 is provided with a first semiconductor layer 1 that serves as a substrate, an insulating layer 2, and a second semiconductor layer 3. That is, the sensor chip 10 has a three-layer structure comprising the first semiconductor layer 1, the insulating layer 2, and the second semiconductor layer 3. The first semiconductor layer 1 and the second semiconductor layer 3 are structured from N-type single crystal silicon layers. The insulating layer 2 is structured from, for example, an SiO₂ layer. The insulating layer 2 is formed on top of the first semiconductor layer 1. Additionally, the second semiconductor layer 3 is formed on top of the insulating layer 2. Consequently, the insulating layer 2 is provided between the first semiconductor layer 1 and the second semiconductor layer 3. The insulating layer 2 functions as an etching stopper when the first semiconductor layer 1 is etched. The second semiconductor layer 3 forms the diaphragm 4. The diaphragm 4 is provided in the center portion of the sensor chip 10.

In the portion that is to form the pressure sensitive region, opening portions 1a and 2a are formed in the first semiconductor layer 1 and the insulating layer 2, to expose the second semiconductor layer 3. In the etching process for forming the opening portion 1a in the first semiconductor layer 1, the first semiconductor layer 1 is removed through anisotropic etching. Consequently, the side walls of the first semiconductor layer 1 are essentially vertical. A recessed portion 12 is formed in the center of the back surface of the second semiconductor layer 3 in a portion that will form the pressure sensitive region. That is, the thickness of the second semiconductor layer 3 is thinner relative to the other portions in the portion that is to form the pressure sensitive region. Here the portion wherein the second semiconductor layer 3 has been made thinner forms the diaphragm 4 for measuring the pressure. Here, in the top view, a square diaphragm 4 is formed in the center portion of the surface of the sensor chip 10. The region corresponding to this diaphragm 4 will form the pressure sensitive region of a pressure sensor 30. The recessed portion 12 is formed in a square shape.

The sensor chip 10 is provided with a thick wall portion 10a surrounding in the diaphragm 4. The thick wall portion 10a is formed at the outer peripheral portion of the sensor chip 10. On the back wall side of the sensor chip 10, the thick wall portion 10a of the sensor chip 10 is anode bonded to a base 11. The base 11 is formed from a rectangular prism having essentially the same size as the sensor chip 10, made from Pyrex™ glass, ceramic, or the like. In the center of the base 11, a through hole 17 is formed through the opening portions 1a and 2a of the first semiconductor layer 1 and the insulating layer 2, to direct the measurement pressure P1 to the back surface side of the diaphragm 4. In other words, the through hole 17 connects the opening portion 1a, the opening portion 2a, and the recessed portion 12.

The square diaphragm 4 is inclined 45° relative to the square sensor chip 10. In the vicinity of the peripheral edge portions of the front surface of the diaphragm 4 are formed four differential pressure or pressure detecting strain gauges 5a through 5d, for detecting differential pressures or pressures through acting as piezo regions. The strain gauges 5a through 5b are arranged so as to be positioned on the diagonal lines b and b of the sensor chip 10. Furthermore, these strain gauges 5a through 5d are formed so as to be parallel to the <110> orientation wherein the piezoresistance coefficient is maximized in the crystal plane orientation (100) of the sensor chip 10.

In this way, strain gauges 5a through 5d that have piezoresistance effects are formed on the top surface side of the second semiconductor layer 3. The strain gauges 5a through 5d are provided on the diaphragm 4. Here four strain gauges 5a through 5d are formed on the second semiconductor layer 3. Note that a metal electrode (not shown) is formed on the top surface of the second semiconductor layer 3 connecting the strain gauges 5a through 5d. The strain gauges 5a through 5d are connected in a bridge circuit. That is, the strain gauges 5a through 5d structure a Wheatstone bridge. The diaphragm 4 is deformed by the pressure differential between the spaces that are partitioned by the diaphragm 4. In the strain gauges 5a through 5d, the resistances will vary in accordance with the amount of deformation of the diaphragm 4. The pressure can be measured by detecting the change in the resistances.

For example, when measurement pressures P1 and P2 are applied to the front and back surfaces of the diaphragm 4, the diaphragm 4 will deform. The specific resistances of the individual strain gauges 5a through 5d will change according to the deformation of the diaphragm 4. As a result, a differential pressure signal for the measurement pressures P1 and P2 will be outputted differentially.

At this time, the rate of change of the resistances in the strain gauges 5a through 5d can be expressed by the following formula:

ΔR/R=π₄₄(σr−σθ)/2 (1)

Here π₄₄ is the coefficient of piezoresistance, σr is the vertical stress in the vicinity of the diaphragm 4, and σθ is the horizontal stress in the vicinity of the diaphragm 4.

The thick wall portion 10a of the sensor chip 10 has only a portion of the back surface thereof bonded to the front surface of the base 11, and the remaining portion is not bonded to the base 11. Consequently, the thick wall portion 10a comprises a non-bonded portion 13 and a bonded portion 13A. The non-bonded portion 13 is disposed towards the outside from the bonded portion 13A. The non-bonded portion 13 is positioned at each of the corner portions of the thick wall portion 10a. The bonded portion 13A surrounds the diaphragm 4 in a frame having an octagonal outer shape.

In the present form of embodiment, stepped portions 14 are formed on the front surface of the base 11. The stepped portions 14 are disposed on the corner portions corresponding to the non-bonded portions 13. Doing so causes each of the corner portions of the thick wall portion 10a to be separated from the base 11, to form the non-bonded portions 13. Gaps, corresponding to the height of the stepped portions 14, are formed between the base 11 and the sensor chip 10 by the non-bonded portions 13. Of course, the stepped portions may conversely be formed on the back surface side of the thick wall portion 10a to provide the non-bonded portions 13.

In the present form of embodiment, as described below, anisotropic etching is used in etching the first semiconductor layer 1. Consequently, the opening portion 1a that is formed in the first semiconductor layer 1 and the opening portion 2a that is formed in the insulating layer 2 are formed essentially vertically. That is, the side walls of the first semiconductor layer 1 and the insulating layer 2 on the pressure sensitive region side are perpendicular to the surface of the sensor chip 10. Furthermore, the second semiconductor layer 3 is etched isotropically in the etching process for the second semiconductor layer 3. Doing so causes side etching of the second semiconductor layer 3, causing the recessed portion 12 to become larger than the opening portion 1a. In this way, the opening dimension of the diaphragm 4 is essentially uniform over the interval from the back surface side of the sensor chip 10 to the insulating layer 2. The insulating layer 2 is disposed at the portion of the diaphragm 4 wherein the opening dimension varies. The opening dimension of the diaphragm 4 varies at the interface between the insulating layer 2 and the second semiconductor layer 3, where the diaphragm dimension becomes larger in the second semiconductor layer 3.

In this way, the recessed portion 12 in the second semiconductor layer 3 is larger than the opening portion 1a and the opening portion 2a. The square pressure sensitive region is one size larger than the square opening portion 1a and opening portion 2a. That is, the opening dimension of the diaphragm 4 is one size larger than the opening dimension of the diaphragm 4 on the back surface side. This enables the pressure sensitive region to be made larger. As a result, this enables an improvement in the measurement accuracy of the pressure sensor 30. Additionally, this enables the area of the bonded portion 13A to be made larger, even when the diaphragm 4 is made larger. As a result, the bonding strength can be increased, even without increasing the size of the chip. Consequently, this enables the pressure sensor 30 to be miniaturized while having higher reliability. As a result, this enables a sensor chip that is smaller with higher performance than in the past.

Here the difference between σr−σθ in equation (1), above, will not go to zero, given geometries and differences in materials, when there has been a change in static pressure or temperature, even if the difference between the measurement pressures P1 and P2 that are applied to the two sides of the diaphragm 4 is zero. Because of this, there is a problem in that an output will be produced by the bridge circuit, and the zero point will shift. In this way, σr will cease to equal σθ when there has been a change in static pressure or static temperature, causing changes in the resistance values of the gauges 5a through 5d. That is, there is a relationship between the deformation of the diaphragm 4 and the bonding surface between the sensor chip 10 and the base 11. Furthermore, the sensor chip 10 and the diaphragm 4 are inclined at about 45°. In this case, the length of that bonding surface, of the bonding surfaces of the sensor chip 10, that is in the direction of the diagonal line b will be longer. Because of this, if the entire back surface of the thick wall portion 10a had been bonded, the vertical stress σr at the edge of the diaphragm 4 would be greater than the horizontal stress σθ at the edge of the diaphragm 4. A zero point shift would result, preventing the differential pressure from being detected with high accuracy.

Given this, in the pressure sensor 30, only a portion of the back surface of the thick wall portion 10a of the sensor chip 10 is bonded to the base 11, in order to mitigate the stress and minimize the crosstalk. That is, stepped portions 14 are formed in portions of the back surface of the thick wall portion 10a. The non-bonded portions 13 are defined through the portions wherein the stepped portions 14 are formed are separate from the base 11, and the bonded portions 13A are defined by portions wherein stepped portions are not formed being bonded to the base 11. The locations wherein stepped portions are formed are each of the corner portions on the back surface of the sensor chip 10, and the non-bonded portions 13 are positioned towards the outside from the bonded portions 13A. The size of the non-bonded portions 13 is formed so that the stress σr in the vertical direction at the edge of the diaphragm 4, and the stress σθ in the horizontal direction at the edge of the diaphragm 4, produced in the strain gauges 5a through 5b will be equal. In other words, optimizing the ratio A/B of the length A of the non-bonded portions 13 and the length B of the bonded portions 13A causes σr=σθ, to minimize the zero point shift due to static pressure and temperature.

Here there is a relationship between the deformation of the diaphragm 4 and the bonding surface between the sensor chip 10 and the base 11. When the square diaphragm 4 is inclined 45° relative to the square sensor chip 10, then the length of the bonding surface, among the bonding surfaces of the sensor chip 10, that is in the direction of the diagonal line becomes longer. Because of this, the vertical stress σr at the edge of the diaphragm 4 will be larger than the horizontal stress σθ at the edge of the diaphragm 4 when the entirety of the back surface of the thick wall portion 10a is bonded. Given this, the non-bonded portions 13 are provided and the ratio of A/B, of the length A thereof and the length B of the bonded portion 13A, can be optimized to cause the stress σr and the stress σθ to be essentially equal. This is able to improve the signal-to-noise ratio.

Causing σr to equal σθ by optimizing A/B in this way is able to reduce the zero point shift due to static pressure or temperature. Note that, in practice, it may be extremely difficult to cause σr and σθ to be exactly equal. In this case, the strain gauges 15a through 15d for detecting static pressure can be provided within the same sensor chip, to correct the output signals of the strain gauges 5a through 5d for detecting differential pressure or pressure. Doing so enables more accurate measurements of the differential pressure or pressure.

Strain gauges 15a through 15d that have piezoresistance effects are formed on the front surface the side of the second semiconductor layer 3. The strain gauges 15a through 15d are formed on the outside of the diaphragm 4. The strain gauges 15a through 15d are formed on the front surface of the sensor chip 10. The strain gauges 15a through 15d are formed on the front surface of the thick wall portion 10a corresponding to the non-bonded portions 13. The static pressure is sensed by the strain gauges 15a through 15d, and the output signals from the differential pressure or pressure detecting strain gauges 5a through 5d are corrected depending on that output signal. The static pressure detecting strain gauges 15a through 15d are disposed on the diagonal lines b and b of the sensor chip 10. Furthermore, the strain gauges 15a through 15d are provided in the positions of each of the corners of the sensor chip 10. Furthermore, the strain gauges 15a through 15d are formed so as to extend in the direction of the <110> crystal orientation wherein the piezoresistance coefficient is maximized in the crystal plane orientation (100) of the sensor chip 10. The strain gauges 15a through 15d are formed through the same diffusion or ion implantation method as the differential pressure or pressure sensing strain gauges 5a through 5d. Furthermore, the strain gauges 15a through 15d are connected in a Wheatstone bridge by leads, not shown. The strain gauges 15a through 15d detect static pressure through changes in the specific resistances accompanying changes in the non-bonded portions 13 due to static pressure. Given this, the strain gauges 15a through 15d use the detected signals thereof to correct the detection signals for the differential pressure or pressure detecting strain gauges 5a through 5d.

The strain gauges 15a through 15d are disposed on the front surface of the non-bonded portions 13. Furthermore, the strain gauges 15a through 15d are disposed at positions that are separated from the center of the diaphragm 4. When the non-bonded portions 13 are provided, then there will be sections wherein the strain produced by static pressure will be high. When the strain gauges 15a through 15d are provided within those sections and on the front surface of the sensor chip 10 in the non-bonded portions 13, then there will be high sensitivity to static pressure, and the sensitivity to differential pressure will be reduced. Doing so makes it possible to reduce the crosstalk, and possible to correct to high precision the detection signals by the strain gauges 5a through 5d for differential pressures or pressures. The strain gauges 15a through 15d may be disposed so that portions thereof extend to the surface of the sensor chip 10 at the bonded portions 13A. Note that preferably the length of the portion extending to the bonded portion 13A is shorter than the length of the portion provided in the non-bonded portions.

Here the vicinities at both ends of the diaphragm 4 are defined as the diaphragm edge portions 6. At the diaphragm edge portions 6, the side edges of the second semiconductor layer 3 extend beyond the outsides of the opening portions 1a and 2a that are formed in the first semiconductor layer 1 and the insulating layer 2. The side edges of the second semiconductor layer 3 are processed into an R-shape. This enables a mitigation of the concentration of stresses. Additionally, because this enables the diaphragm 4 to be made larger, this enables a pressure sensor 30 that is small and that has high accuracy.

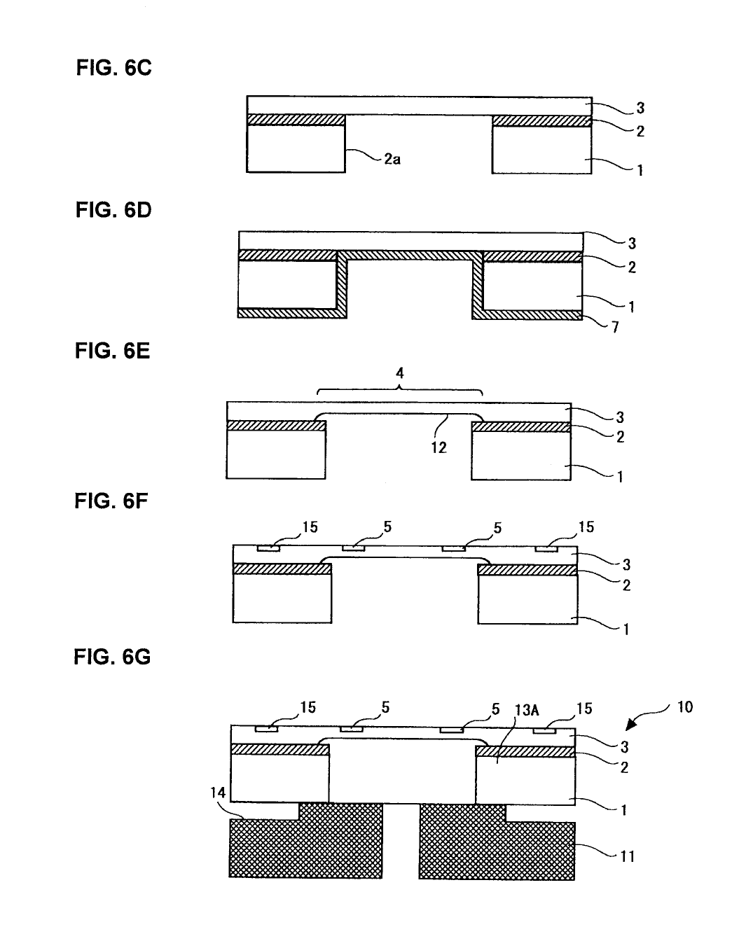

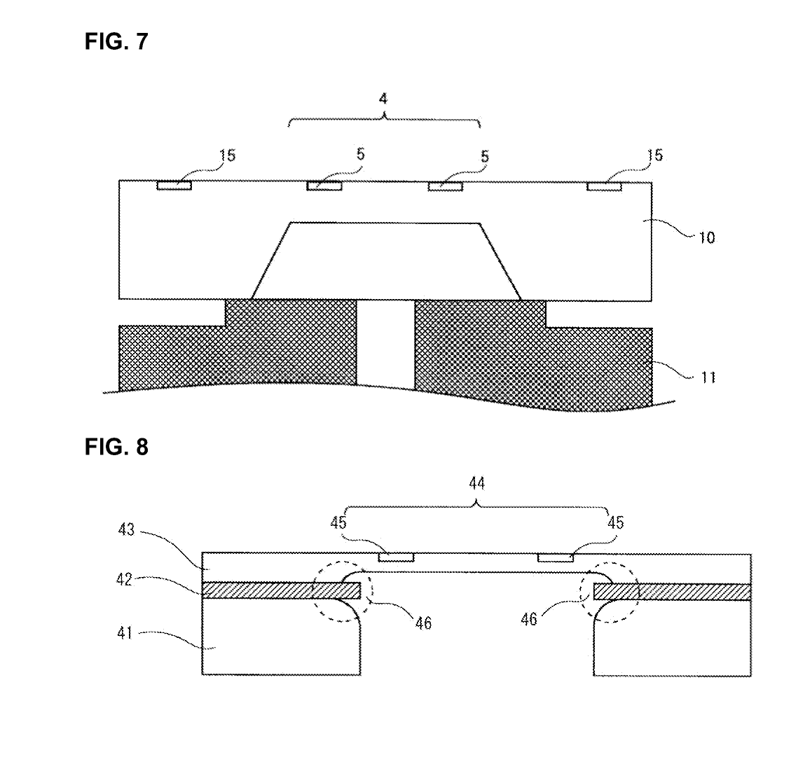

The method for manufacturing the pressure sensor 30 will be explained next using FIG. 6A through FIG. 6G. FIG. 6A through FIG. 6G are process cross-sectional diagrams illustrating the method for manufacturing the semiconductor sensor. First, as illustrated in FIG. 6A, a Silicon On Insulator (SOI) wafer is prepared, comprising the first semiconductor layer 1, an insulating layer 2 that is approximately 0.5 μm thick, and the second semiconductor layer 3. In fabricating this SOI wafer, the SIMOX (Separation by IMplanted OXygen) technology wherein an SiO₂ layer is produced through implanting oxygen into a silicon substrate may be used, the SDB (Silicon Direct Bonding) technology, wherein two silicon substrates are bonded together, may be used, or another method may be used.

The second semiconductor layer 3 is planarized and reduced in thickness. For example, the second semiconductor layer 3 is polished to a specific thickness (for example 80 μm) using, for example, the polishing method known as CCP (Computer-Controlled Polishing).

An SiO₂ layer or a resist (not shown) is formed on the bottom surface of the SOI wafer that is formed in this way. An opening portion is formed in the SiO₂ layer or the resist in a portion corresponding to the pressure sensitive region (the region wherein the diaphragm 4 will be formed). After this, the SiO₂ layer or resist patterned in this way is used as an etching mask for forming the diaphragm, and the first semiconductor layer 1 is etched (first etching). Here the first semiconductor layer 1 is processed through dry etching. More specifically, the first semiconductor layer 1 is etched through an ICP Bosch process. Anisotropic etching is performed through the Bosch process, and thus the side wall surfaces of the first semiconductor layer 1 are essentially vertical, as illustrated in FIG. 6B.

Note that in the Bosch process an etching step and a passivating step (deposition step) are performed alternatingly. The etching step and the passivating step are alternated every few seconds. In the etching step, isotropic etching is performed using, for example, SF₆ gas. In the passivating step, the side walls are protected using a fluorocarbon gas (such as C₄F₈). That is, a layer for protecting the side walls is deposited on the first semiconductor layer 1. Doing so suppresses the side etching in the etching step. This makes it possible to perform anisotropic etching on the first semiconductor layer 1. Using the Bosch process in this way makes it possible to etch the silicon deeply, to form a vertical trench structure.

Here the insulating layer 2 functions as an etching stopper. Because of this, the etching advances steadily in the aforementioned opening portion, but the etching rate drops when the etching reaches at the insulating layer 2. In this way, the first semiconductor layer 1 is removed until the insulating layer 2 is exposed. This forms an opening portion in the first semiconductor layer 1 to expose the insulating layer 2 in the center portion of the chip that will form the pressure sensor. Insofar as it is anisotropic etching, the first semiconductor layer 1 may be etched by etching other than the Bosch process.

Following this, the first semiconductor layer 1 is used as an etching mask when etching the insulating layer 2. The insulating layer 2 is processed through wet etching using, for example, a solution such as HF. Of course, the insulating layer 2 may be etched using a different etchant instead, or maybe etched using dry etching. The insulating layer 2 that was exposed through etching the first semiconductor layer 1 is removed, to form the structure illustrated in FIG. 6C. In this way, an opening portion 2a is formed in insulating layer 2, to expose the second semiconductor layer 3 in the portion that will form the pressure sensitive region. The diameters of the opening portions 1a and 2a in the first semiconductor layer 1 and the insulating layer 2 are essentially identical.

Next, when a passivating layer 7 is formed to a specific thickness on the surface of the wafer, the structure will be as illustrated in FIG. 6D. The passivating layer 7 is formed over the entirety of the wafer surface. Consequently, the passivating layer 7 is formed covering the first insulating layer 1. The passivating layer 7 is also formed on the side surfaces of the insulating layer 2 and on the exposed portion of the second semiconductor layer 3. That is, the passivating layer 7 is deposited on the surface of the second semiconductor layer 3 in the portion at which the opening portions 1a and 1b are formed in the first semiconductor layer 1 and the insulating layer 2. The passivating layer 7 protects the first semiconductor layer 1 from side etching in the etching process for the second semiconductor layer 3, described below.

The passivating layer 7 is formed through performing, for example, the passivating step of the Bosch process. That is, the passivating layer 7 is deposited using a gas that includes carbon atoms and fluorine atoms, such as C₄F₈. Here the passivating layer 7 is formed from a fluorocarbon layer, because of the use of the fluorocarbon gas. This deposits the passivating layer 7 over the entirety of the surface of the wafer. Note that the passivating layer may be formed through repeating a passivating step that is several seconds long, or the passivating layer 7 may be formed through performing a continuous passivating step over an extended period of time. Furthermore, the passivating layer may instead be formed through a process other than the Bosch process. For example, the passivating layer may be formed from photoresist, or the like. Conversely, the passivating layer 7 may be deposited using a chemical vapor deposition (CVD) process, or the like. Furthermore, the passivating layer 7 is formed to a thickness such that there will be no side etching of the first semiconductor layer 1 in the subsequent process for etching the second semiconductor layer 3. That is, the thickness to which the passivating layer 7 is formed is set in consideration of the amount of etching for the second semiconductor layer 3. Furthermore, the passivating layer 7 need not be formed on the other portions, insofar as it is formed on the side walls of the first semiconductor layer 1.

Thereafter, with the passivating layer 7 having been formed, the second semiconductor layer 3 is etched (second etching). Doing so forms a recessed portion in the second semiconductor layer 3 that will form the diaphragm 4. Here an etching step of the Bosch process, or the like, may be used. That is, dry etching is performed using a gas (SF₆) that contains sulfur atoms and fluorine atoms. Side etching of the first semiconductor layer 1 is suppressed because of the formation of the passivating layer 7 on the side walls of the first semiconductor layer 1. At this time, the first semiconductor layer 1 is not etched, and no notch is formed at the interface between the first semiconductor layer 1 and the insulating layer 2. It is possible to position the side edge of the first semiconductor layer 1 in the same position as the side edge of the insulating layer 2 at the interface between the first semiconductor layer 1 and the insulating layer 2. On the pressure sensitive region side, the side edge of the first semiconductor layer 1 and the side edge of the insulating layer 2 can be positioned coincidentally. Note that the depth of etching of the second semiconductor layer 3 is controlled to a specific minute value (between about 5 and 50 μm) through time control.

Additionally, performing the dry etching in a state wherein a bias voltage is applied to the second semiconductor layer 3 accelerates the ions towards the second semiconductor layer 3. Because of this, the velocity of the ions in the vertical direction will be higher than the velocity in the horizontal direction. The majority of the ions within the plasma will be directed towards the second semiconductor layer 3 in the opening portions 1a and 2a of the first semiconductor layer 1 and the insulating layer 2. Consequently, the frequency of ion impingement on the passivating layer 7 that is formed on the surface of the second semiconductor layer 3 will be high, causing the passivating layer 7 that is formed on the surface of the second semiconductor layer 3 to be etched with a somewhat elevated etching rate. Given this, the passivating layer 7 that is formed on the surface of the second semiconductor layer 3 will be removed quickly, exposing the second semiconductor layer 3.

On the other hand, the frequency of ion impingement on the passivating layer 7 that is provided on the side walls of the first semiconductor layer 1, for the same reasons set forth above, will be relatively low, so the etching rate of the passivating layer 7 that is formed on the side wall surfaces of the first semiconductor layer 1 will be reduced. Consequently, the etching rate in the vertical direction of the passivating layer 7 in the opening portions 1a and 2a will be higher than the etching rate in the horizontal direction. As a result, the second semiconductor layer 3 will be etched in a state wherein the passivating layer 7 that is formed on the side wall surfaces of the first semiconductor layer 1 is still in place.

Furthermore, when the passivating layer 7 is removed from the surface of the second semiconductor layer 3 to expose the second semiconductor layer 3, the second semiconductor layer 3 is then etched isotropically. Consequently, there will be side etching of the second semiconductor layer 3. The portion of the second semiconductor layer 3 that is removed through side etching will extend beyond the outside of the opening portions 1a and 2a formed in the first semiconductor layer 1 and the insulating layer 2. That is, the location of the side edge of the second semiconductor layer 3 will be offsetted from the location of the side edges of the first semiconductor layer 1 and the insulating layer 2. The recessed portion 12 for forming the diaphragm 4 will be larger than the opening portions 1a and 2a in the first semiconductor layer 1 and the insulating layer 2. Following this, when the wafer is cleaned in a chemical solution, or the like, and the passivating layer 7 that is formed on the wafer is removed, the structure will be as illustrated in FIG. 6E. In this way, side etching is performed on the second semiconductor layer 3 to form a recessed portion 12, in the second semiconductor layer 3, that is larger than the etched portion of the insulating layer 2. Doing so enables the pressure sensitive area to be made larger. The side edges of the second semiconductor layer 3 are processed into an R-shape through side etching. This enables the mitigation of the concentration of stresses.

Doing this forms a diaphragm 4 in the second semiconductor layer 3. The etching of the second semiconductor layer 3 is a minute amount, between about 5 and 50 μm, so there is no variability in the thickness of the etching, and thus the diaphragm 4 can be formed with a uniform thickness. This enables an improvement in the measurement accuracy. This also enables an increase in strength of the diaphragm edge portion 6. Additionally, the insulating layer does not remain on the diaphragm 4, enabling an increase in the strength of the diaphragm edge portion 6.

Furthermore, the Bosch process passivating layer is used in the process for forming the passivating layer 7, and the Bosch process etching step, and the like, is used in the process of etching the second semiconductor layer 3. Doing so enables continuous processing within the same equipment, enabling an increase in productivity. Furthermore, because the same equipment can be used through using the Bosch process in the first etching, this enables an even greater increase in productivity. Of course, the second semiconductor layer 3 may instead be etched through a different etching process.

Strain gauges (piezoresistance regions) 5 and 15 are formed from P-type silicon, or the like, through diffusion of impurities or through ion implantation into the top surface of the second semiconductor layer 3. The strain gauges 5 are formed in the diaphragm 4 of the second semiconductor layer 3. Additionally, the strain gauges 15 are formed to the outside of the diagram 4. This causes the structure to be as illustrated in FIG. 6F. Note that the strain gauge 5 is any of 5a through 5d, and the strain gauge 15 is any of 15a through 15b. Following this, an SiO₂ layer (not shown) is formed on the top surface of the second semiconductor layer 3, and after the formation of contact holes in the SiO₂ layer over the strain gauges 5, metal electrodes (not shown) are deposited through vapor deposition in order to make electrical contact with the strain gauges 5 at the contact hole portions. Note that the process for forming the metal electrodes may be performed anywhere between FIG. 6A and FIG. 6E.

After this, the base 11 is bonded to the back surface side of the sensor chip 10. Here only the bonded portions 13A are bonded, and the non-bonded portions 13 are not bonded. This produces the structure illustrated in FIG. 6G. The sensor chip 10 and the base 11 are directly bonded through, for example, anode bonding. This completes the fabrication of the pressure sensor.

As described above, the second etching is performed in a state wherein the passivating layer 7 is formed on the side walls of the first semiconductor layer 1. Because the second etching is performed using isotropic etching, the recessed portion 12 of the second semiconductor layer 3 can be made larger than the opening portions 1a and 2a. Doing so enables the bonded portions 13A to be made larger, even when the area of the pressure sensitive region is increased in size. This enables an improvement in the reliability of the bonding. The side edge of the second semiconductor layer 3 on the pressure sensitive region side being processed into the R-shape enables a mitigation of the concentration of stresses. This both enables miniaturization of the sensor chip 10 and enables a highly reliable sensor.

Note that while, in the explanations set forth above, the explanations were for an example that uses an insulating layer 2, it is added that the provision of the insulating layer in the present pressure sensor is not absolutely necessary in so far as a manufacturing method is used that is able to ensure adequate thickness for the second semiconductor layer 3 through being able to adjust the etching rate and time of the first etching, even if there is no insulating layer 2 (stopper). Furthermore, while in the explanations set forth above the diaphragm was formed in a square shape, it may be formed instead into a polygon or a circle. When the diaphragm 4 is a square, then, as illustrated in FIG. 2C, the centers of the diaphragm 4 and of the sensor chip 10 are caused to be coincident.

The present invention may be applied to pressure sensors for measuring pressure using diaphragms, and to the manufacturing methods thereof.

While the invention has been particularly shown and described with reference to a number of preferred embodiments thereof, it will be understood by those skilled in the art that various changes in form and details may be made therein without departing from the sprit and scope of the invention. Accordingly, the invention is to be limited only by the scope of the claims and their equivalents.

1-23. (canceled)

24. A pressure sensor having a sensor chip and a pressure sensitive region comprising:
a first semiconductor layer and a second semiconductor layer;
the first semiconductor layer having an open portion with side walls that are substantially perpendicular to a surface of the second semiconductor layer;
a recessed portion formed in the surface of the second semiconductor layer of the pressure sensitive region, the recessed portion of the second semiconductor layer being larger than the open portion of the first semiconductor layer; and
wherein the pressure sensitive region is a diaphragm.

25. A pressure sensor having a sensor chip and a pressure sensitive region comprising:
a first semiconductor layer;
an insulating layer formed on top of the first semiconductor layer;
a second semiconductor layer formed on top of the insulating layer;
an open portion formed in the first semiconductor layer and in the insulating layer, wherein
the open portion has side walls that are substantially perpendicular to a plane defined by the area where the second semiconductor layer is formed on top of the insulating layer;
a recessed portion formed in the second semiconductor layer of the pressure sensitive region; and
wherein at the interface between the insulating layer and the first semiconductor layer, the position of the side walls of the first semiconductor layer and the insulating layer are coincident with a side of the recessed portion of the pressure sensitive region; and
wherein the pressure sensitive region is a diaphragm.

26. The pressure sensor of claim 25, wherein the recessed portion formed in the second semiconductor layer is larger than the open portion of the insulating layer.

27. The pressure sensor of claim 24, wherein the diaphragm is in the shape of a polygon.

28. The pressure sensor of claim 25, wherein the diaphragm is in the shape of a polygon.

29. The pressure sensor of claim 24, wherein the diaphragm is in the shape of a circle.

30. The pressure sensor of claim 25, wherein the diaphragm is in the shape of a circle.

31. The pressure sensor of claim 24, further comprising:
a base bonded to the sensor chip at a bonding portion, the base and the sensor chip defining a gap at a peripheral edge of the bonding portion between the base and the sensor chip.

32. The pressure sensor of claim 25, further comprising:
a base bonded to the sensor chip at a bonding portion, the base and the sensor chip defining a gap at a peripheral edge of the bonding portion between the base and the sensor chip.

33. A method for manufacturing a pressure sensor having a sensor chip that is provided with a first semiconductor layer and a second semiconductor layer with a pressure sensitive region that is a diaphragm, comprising:
etching the first semiconductor layer to form an open portion with sidewalls, the side walls being substantially perpendicular to a surface of the second semiconductor layer;
forming a passivating layer repetitively on the side walls of the first semiconductor layer; and
forming the diaphragm by etching the surface of the second semiconductor layer at a portion that will form the pressure sensitive region, after the formation of a passivating layer.

34. The method of claim 33, wherein forming the diaphragm comprises etching the surface of the second semiconductor layer to form a recessed portion that is larger than the side walls of the open portion of the first semiconductor layer.

35. A method for manufacturing a pressure sensor having an insulating layer between a first semiconductor layer and a second semiconductor layer for forming a diaphragm, comprising:
etching the first semiconductor layer to form an opening with side walls substantially perpendicular to a surface of the second semiconductor layer;
etching the insulating layer so that the side walls of the opening will be substantially perpendicular to the surface of the second semiconductor layer;
forming a passivating layer repetitively on the side walls of the first semiconductor layer; and
forming the diaphragm by etching a portion of the second semiconductor layer that will form the pressure sensitive region, after the formation of the passivating layer.

36. The method of claim 35, wherein forming the diaphragm comprises etching the second semiconductor layer to form a recessed portion that is larger than the side walls of the opening.

37. The method of claim 35, wherein etching the first semiconductor layer comprises using the insulating layer as an etching stopper.

38. The method of claim 36, wherein etching the first semiconductor layer comprises using the insulating layer as an etching stopper.

39. The method of claim 33, wherein forming the passivating layer comprises forming the passivating layer from a fluorocarbon layer.

40. The method of claim 35, wherein forming the passivating layer comprises forming the passivating layer from a fluorocarbon layer.

41. The method of claim 33, wherein the diaphragm is formed in a polygon shape.

42. The method of claim 35, wherein the diaphragm is formed in a polygon shape.

43. The method of claim 33, wherein the diaphragm is formed in a circular shape.

44. The method of claim 35, wherein the diaphragm is formed in a circular shape.

45. The method of claim 33, further comprising:
bonding a base to the sensor chip at a bonding portion, the base and the sensor chip defining a gap at a peripheral edge of the bonding portion between the base and the sensor chip.

46. The method of claim 35, further comprising:
bonding a base to the sensor chip at a bonding portion, the base and the sensor chip defining a gap at a peripheral edge of the bonding portion between the base and the sensor chip.
